(19) United States
(12) Patent Application Publication
(10) Pub. No.: US 2006/0081871 A1
(43) Pub. Date: Apr. 20, 2006

(54) Multiple light-emitting diode arrangement

(75) Inventor: Klaus Streubel, Laaber (DE)

Correspondence Address: COHEN, PONTANI, LIEBERMAN & PAVANE, 551 FIFTH AVENUE, SUITE 1210, NEW YORK, NY, 10176, US

(73) Assignee: Osram Opto Semiconductors GmbH, Regensburg (DE)

(21) Appl. No.: 11/238,516

(22) Filed: Sep. 30, 2005

(30) Foreign Application Priority Data
Sep. 30, 2004 (DE) 102004047763.9

(51) Int. Cl. H01L 33/00

(52) U.S. Cl. 257/100

(57) ABSTRACT

A radiation-emitting semiconductor component comprising a plurality of semiconductor bodies (10, 20, 30) which each have an active zone (11, 21, 31) and during operation emit light having in each case a different central wavelength (λ₁₀, λ₂₀, λ₃₀) and an assigned spectral bandwidth (Δλ₁₀, Δλ₂₀, Δλ₃₀), so that the mixing of this light gives rise to the impression of white light. In the case of at least one of the semiconductor bodies (10), the emission wavelength varies in the active zone (11) in a predetermined manner, so that the spectral bandwidth (Δλ₁₀) of the emitting light is increased as a result.

### RELATED APPLICATIONS

This patent application claims the priority of German patent application no. 10 2004 047 763.9 filed Sep. 30, 2004, the disclosure content of which is hereby incorporated by reference.

### FIELD OF THE INVENTION

The present invention relates to a multiple light-emitting diode arrangement comprising a plurality of semiconductor bodies which each have an active zone and during operation emit light having in each case a different central wavelength and an assigned spectral bandwidth.

### BACKGROUND OF THE INVENTION

In known multiple light-emitting diode arrangements of this type, a plurality of semiconductor bodies are arranged in a common housing. The semiconductor bodies emit light having different wavelengths during operation, for example in the red, green and blue spectral ranges, so that overall such a component emits mixed-color or white light. The color locus of the light generated can be varied through suitable driving of the individual semiconductor bodies. In order to generate white light, it is necessary for this purpose to choose a color locus that lies within the white region. In the CIE color space, the white region surrounds the so-called white point with the color locus x=y=0.33.

In lighting engineering, conventional white light sources such as, for example, incandescent lamps or discharge lamps are characterized inter alia by the color temperature and the color rendering index.

The color temperature is the temperature of a black body radiator whose color locus is closest to the color locus of the white light source to be characterized (also known as Correlated Color Temperature, CCT).

The color rendering index specifies the magnitude of the average color deviation of defined test color fields upon illumination with the light source to be characterized in comparison with illumination with a defined standard light source. The maximum color rendering index is 100 and corresponds to a light source for which no color deviations occur. Further details on the measurement and definition of the color rendering index are specified in DIN 6169.

Consequently, the color temperature is a measure of the color locus of a white light source as referred to the black body radiator, while the color rendering index specifies the quality of the light source with regard to an as far as possible uncorrupted color impression of an object upon illumination with this light source.

In the case of the known multiple light-emitting diode arrangements mentioned above, the color temperature can be set within certain limits through corresponding setting of the color locus by means of suitable driving of the individual semiconductor bodies. By contrast, the color rendering index is generally fixedly prescribed by the structures and the material of the semiconductor bodies. This color rendering index range typically lies in the range of 45 to 55. In comparison with this, conventional incandescent lamps have a color rendering index of 98 or more.

### SUMMARY OF THE INVENTION

It is an object of the present invention to provide a multiple light-emitting diode arrangement of the type mentioned in the introduction with an improved color rendering index.

This and other objects are attained in accordance with one aspect of the present invention directed to a radiation-emitting semiconductor component comprising a plurality of semiconductor bodies which each have an active zone and during operation emit light having in each case a different central wavelength and an assigned spectral bandwidth. In the case of at least one of the semiconductor bodies, the emission wavelength of the active zone varies in a predetermined manner, and the spectral bandwidth of the emitted light is increased as a result.

The impression of white light preferably arises as a result of the mixing of the light emitted by the semiconductor bodies. The central wavelength is also referred to as peak wavelength. In case of doubt the spectral bandwidth is to be understood as the full spectral width at half maximum (Full Width Half Maximum, FWHM).

In this case, the invention is based on the concept that, in the case of the multiple light-emitting diode arrangements mentioned above, the individual semiconductor bodies emit light with a comparatively small spectral bandwidth and, consequently, the entire emission spectrum of the component has a plurality of individual spectral lines. In contrast to this, incandescent lamps exhibit a broad continuous spectrum. In order to improve the color rendering of a multiple light-emitting diode arrangement, provision is therefore made, within the scope of the invention, for increasing the spectral bandwidth of the light emitted by the individual semiconductor bodies in order thus to approximate the emission spectrum of the multiple light-emitting diode arrangements to the emission spectrum of an incandescent lamp. It has surprisingly been found in this case, within the scope of the invention, that even a comparatively small increase in the spectral bandwidth in the case of only one of the semiconductor bodies can lead to a significant increase in the color rendering index.

Preferably, in one refinement of the invention, the radiation emitted overall by the semiconductor component comprises only the light emitted by the semiconductor bodies, so that there is thus no need to provide a further emitter which, in particular, brings about a spectral widening, such as a phosphor, for example. In this case, the increase in the bandwidth of the light emitted by the at least one semiconductor body is advantageous since an approximation of the emission spectrum to the emission spectrum of an incandescent lamp or an improvement of the color rendering index is achieved solely with the semiconductor bodies.

As an alternative, in another refinement of the invention, it may be provided that a luminescence conversion element, in the form of a phosphor, for instance, which may be distributed for example in the form of phosphor particles in a matrix material, may be arranged downstream of one of the semiconductor bodies, a plurality or else all of the semiconductor bodies in the emission direction. Said luminescence conversion element converts the light generated by the semiconductor body or semiconductor bodies into light having a different wavelength. It is thereby possible, if appropriate, to obtain a further improved approximation of the emission spectrum to the emission spectrum of an incandescent lamp or a more extensive improvement of the color rendering index.

In one advantageous development of the invention, the active zone of the at least one semiconductor body is embodied in such a way that the emission wavelength increases or decreases in the vertical direction within said active zone.

In a first preferred variant of the invention, this is achieved by virtue of the fact that the active zone comprises a multiple quantum well structure whose quantum wells have different quantization energies. The individual quantum wells thus emit light having a slightly different central wavelength, so that the multiple quantum well structure overall generates light having an increased spectral bandwidth.

Within the scope of the present invention, the designation quantum well structure encompasses all structures in which charge carriers experience a quantization of their energy states as a result of confinement. In particular, the designation quantum well structure comprises no indication regarding the dimensionality of the quantization. It thus encompasses, inter alia, quantum wells, quantum wires and quantum dots and also all combinations of these structures.

In a second variant of the invention, the active zone contains a semiconductor material whose composition changes within the active zone in the vertical direction in a predetermined manner. This so-called compensation gradient is embodied such that the band gap of the semiconductor material increases or decreases in the vertical direction and, consequently, the emission wavelength correspondingly changes in the vertical direction in such a way that the spectral bandwidth of the emitted light is increased overall. Suitable semiconductor material for this variant is, in particular, InGaAlP since, in the case of this quaternary semiconductor material system, the wavelength can be set independently of the lattice constant within predetermined limits and it is thus possible to form a composition gradient without a lattice mismatch.

In a third variant of the invention, the active zone may also comprise a plurality of active layers having different emission wavelengths which, by way of example, each comprise a corresponding quantum well structure. In this case, the difference between the emission wavelengths is expediently so small that the spectrum of the light emitted by the semiconductor body overall essentially has a single, widened emission line and, in particular, does not have a plurality of local maxima.

It should be noted that the variants mentioned can also be combined, for example in the form of a multiple quantum well structure in which the composition of the semiconductor material and/or the dimensioning of the quantum wells changes in the vertical direction.

Preferably, in the case of the invention, the at least one semiconductor body has a coupling-out area arranged in a vertical distance of the active zone, the emission wavelength decreasing within the active zone in the direction of the coupling-out area. What is thereby achieved is that the shorter-wave radiation is generated on the side facing the coupling-out area, and, consequently, there is a reduction of the reabsorption of the generated radiation within the active zone.

In a first preferred embodiment of the invention, the plurality of semiconductor bodies comprises a first semiconductor body emitting in the red spectral range, a second semiconductor body emitting in the green spectral range, and a third semiconductor body emitting in the blue spectral range, the impression of white light arising as a result of the mixing of the light emitted by the first, second and third semiconductor bodies.

As an alternative, in a second preferred embodiment of the invention, the plurality of semiconductor bodies comprises a first semiconductor body emitting in the yellow or orange spectral range and a second semiconductor body emitting in the blue or blue-green spectral range, the impression of white light arising as a result of the mixing of the light emitted by the first and second semiconductor bodies.

In this case, the first embodiment has the advantage that the color locus or the color temperature can be set freely within comparatively large limits through suitable driving of the semiconductor bodies mentioned. In the case of the second embodiment, on the other hand, the number of semiconductor bodies is advantageously reduced.

Preferably, in the case of the invention, the spectral bandwidth is increased through variation of the emission wavelength within the active zone in the case of that semiconductor body which has the highest central wavelength. It has been found that even an increase in the spectral bandwidth only in the case of this semiconductor body can lead to a significant increase in the color rendering index. In general, this semiconductor body emits in the yellow, yellow-orange or red spectral range, so that a material from the abovementioned advantageous material system InGaAlP can be used for the active zone.

It is further preferred, in the case of a multiple light-emitting diode arrangement according to the invention, for the increased spectral bandwidth to be greater than or equal to 30 nm, particularly preferably greater than or equal to 40 nm. The increase in the spectral bandwidth in the case of the invention is generally dimensioned in such a way that the color rendering index of the light emitted by the component is greater than or equal to 60, preferably greater than or equal to 80, particularly preferably greater than or equal to 90.

### BRIEF DESCRIPTION OF THE DRAWINGS

FIG. 1 shows a schematic detail sectional view of the exemplary embodiment of a multiple light-emitting diode arrangement according to an embodiment of the invention,

FIG. 2 shows a graphical illustration of the spectral composition of the light emitted by the exemplary embodiment,

FIG. 3 shows a graphical illustration of the electronic band structure of an active zone in the exemplary embodiment of a multiple light-emitting diode arrangement according to an embodiment of the invention,

FIGS. 4A and 4B show a schematic plan view and a schematic side view, respectively, of the exemplary embodiment of a multiple light-emitting diode arrangement according an embodiment of the invention.

### DETAILED DESCRIPTION OF THE DRAWINGS

In the drawings, identical or identically acting elements are provided with the same reference symbols.

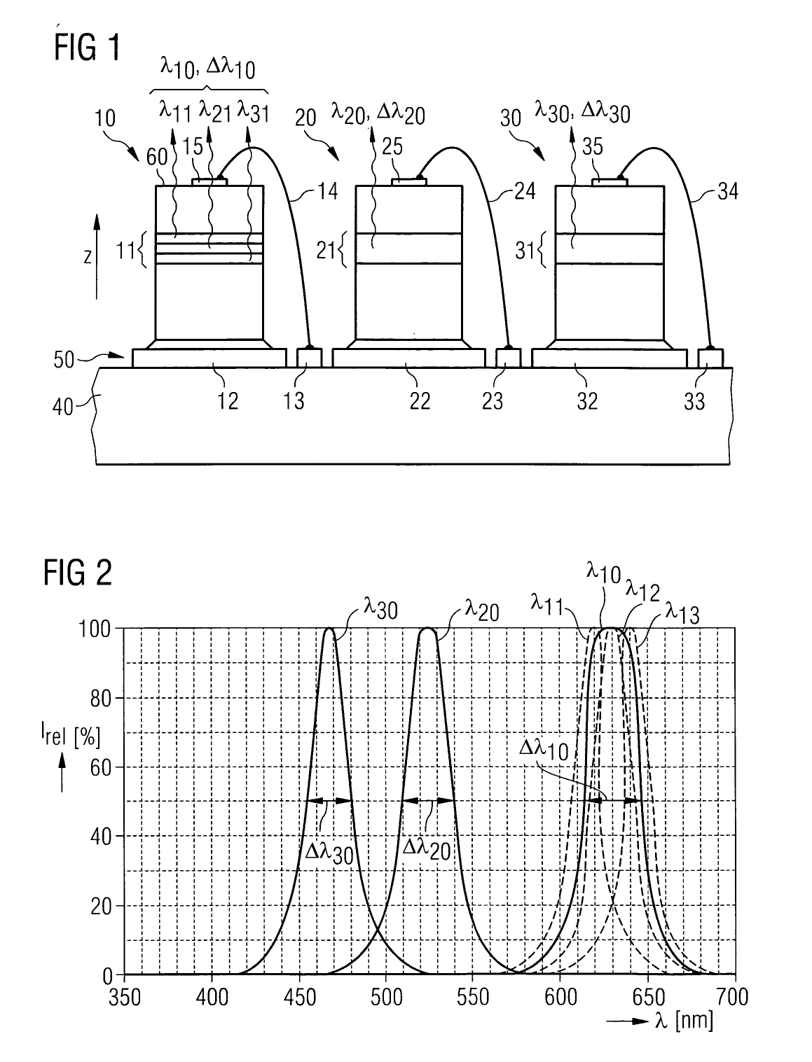

The exemplary embodiment illustrated in FIG. 1 has a first semiconductor body 10, a second semiconductor body 20 and a third semiconductor body 30. The semiconductor bodies 10, 20, 30 are each mounted on a chip mounting region 12, 22, 32 of a leadframe 50. The leadframe 50 is fixed to a housing basic body 40, which is only partially illustrated in FIG. 1.

On that side which is remote from the leadframe 50, the semiconductor bodies 10, 20, 30 are each provided with a contact metalization 15, 25, 35. A wire connection 14, 24, 34 is in each case led from said contact metalization to a wire terminal 13, 23, 33 of the leadframe 50.

During operation, the semiconductor body 10 emits light having a central wavelength λ₁₀ and a spectral bandwidth Δλ₁₀, the semiconductor body 20 emits light having a central wavelength λ₂₀ and a spectral bandwidth Δλ₂₀, and the semiconductor body 30 emits light having a central wavelength λ₃₀ and a spectral bandwidth Δλ₃₀. The central wavelength λ₁₀ may for example lie in the red spectral range, for instance at 620 nm, the central wavelength λ₂₀ may lie in the green spectral range, for instance at 530 nm, and the central wavelength λ₃₀ may lie in the blue spectral range, for instance at 470 nm.

In a second embodiment of the invention, two semiconductor bodies, of which one may emit in the blue spectral range, for instance at 470 nm, and one may emit in the orange spectral range, for instance at 590 nm, may be provided instead of the three semiconductor bodies illustrated by way of example in FIG. 1.

FIG. 2 schematically illustrates the emission spectra of the three semiconductor bodies 10, 20, 30 for the exemplary embodiment illustrated in FIG. 1. The relative intensity of the emitted light is plotted as a function of the wavelength.

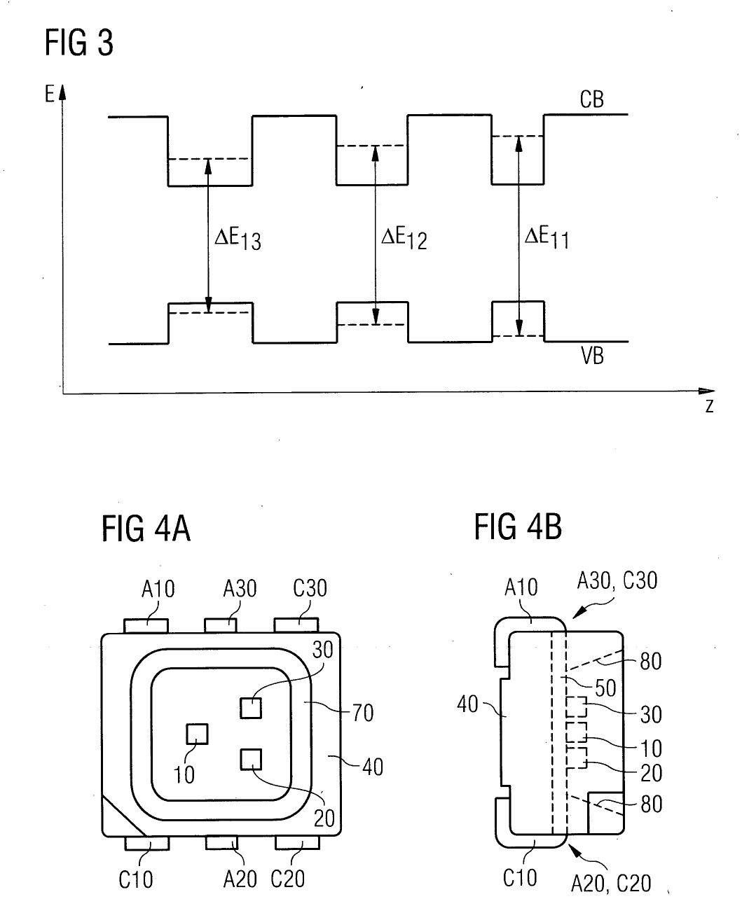

In contrast to the spectra of the light emitted by the semiconductor bodies 20 and 30, having the central wavelength λ₂₀ and the spectral bandwidth Δλ₂₀ and, respectively, λ₃₀ and the spectral bandwidth Δλ₃₀, the spectrum of the light emitted by the semiconductor body 10, having the central wavelength λ₁₀ and the spectral bandwidth Δλ₁₀, is composed of a plurality of spectral lines having different central wavelengths λ₁₁, λ₁₂ and λ₁₃. These spectral lines arise by virtue of the fact that the emission wavelength varies in the vertical z direction (indicated by the z arrow in FIG. 1) in the active zone 11 of the semiconductor body 10. This is explained in even greater detail below with reference to FIG. 3.

Overall, the light emitted by the semiconductor body 10 has a spectrum formed by the sum of the individual spectral lines with the emission wavelengths λ₁₁, λ₁₂ and λ₁₃. In this case, the increase in the spectral bandwidth λ₈₀ ₁₀ is proportionate to the magnitude of the variation of the emission wavelength within the active zone 11.

In the case of the exemplary embodiment shown, the spectral bandwidth Δλ₁₀ is approximately 20 nm, the spectral bandwidth Δλ₂₀ is approximately 35 nm and the spectral bandwidth Δλ₃₀ is approximately 20 nm. This results in a white light source having a color rendering index of 63 given suitable driving of the multiple light-emitting diode arrangement. Conventionally, in particular the linewidth of the semiconductor body 10 exhibiting the longest-wave emission is smaller and is approximately 15 nm, which results in a significantly smaller color rendering index of approximately 50.

The spectral bandwidths Δλ₁₀, Δλ₂₀ and Δλ₃₀ and also the color rendering index (CRI) are summarized in the following table for three variations A, B and C of the exemplary embodiment with in each case a different spectral bandwidth of the semiconductor body exhibiting the longest-wave emission. The corresponding data of a conventional multiple light-emitting diode arrangement are likewise specified for comparison. The associated central wavelengths λ₁₀, λ₂₀ and λ₃₀, as already specified, are 620 nm, 530 nm and 470 nm, respectively.

| Variation | Δλ₁₀ (nm) | Δλ₂₀ (nm) | Δλ₃₀ (nm) | CRI |
|---|---|---|---|---|
| A | 20 | 35 | 20 | 63 |
| B | 30 | 35 | 20 | 80 |
| C | 40 | 35 | 20 | 90 |
| Prior art | 15 | 35 | 20 | 50 |

It has surprisingly been shown, within the scope of the invention, that just by increasing the spectral bandwidth of the semiconductor body exhibiting the longest-wave emission, it is possible to obtain a significant increase in the color rendering index.

For the second embodiment of the invention with two semiconductor bodies, the table below correspondingly specifies the spectral bandwidths and the color rendering index for three variations A, B and C with different spectral bandwidths of the semiconductor body exhibiting the longest-wave emission and also, for comparison, the corresponding data of a multiple light-emitting diode arrangement according to the prior art. As already specified, the associated central wavelengths λ₁₀ and λ₂₀ here are 590 nm and 470 nm, respectively.

| Variation | Δλ₁₀ (nm) | Δλ₂₀ (nm) | CRI |
|---|---|---|---|
| A | 20 | 20 | 56 |
| B | 30 | 20 | 64 |
| C | 40 | 20 | 65 |
| Prior art | 15 | 20 | 47 |

A significant increase in the color rendering index can once again be obtained just by increasing the spectral bandwidth in the case of the semiconductor body exhibiting the longest-wave emission.

FIG. 3 schematically illustrates an exemplary band structure of the semiconductor body 10.

The active zone 11 of the semiconductor body 10 is formed as a multiple quantum well structure in this case. FIG. 3 plots the profile of the respective energy level in the z direction for the conduction band CB and the valence band VB.

The band structure has a plurality of quantum wells, the width of the quantum wells decreasing with increasing z direction. On account of the dependence of the quantization energy on the extent of the quantum well, this has the effect that the quantization energy of the individual quantum wells increases with increasing z direction. Consequently, the quantum well with the quantization energy ΔE₁₃ illustrated on the left emits longer-wave radiation than the quantum wells with the quantization energies ΔE₁₂ and ΔE₁₁, respectively, arranged in increasing z direction.

A similar variation of the emission wavelength of the emitted light of the active zone can also be achieved, in the case of the invention, by virtue of the fact that the composition of the semiconductor material varies in the active zone in a predetermined manner in such a way that the band gap changes within the active zone, preferably in the vertical direction. It should be noted that such a variation, also referred to as composition gradient, may also be combined with the abovementioned quantum well structure, so that, by way of example, a quantum well structure is thus formed in which the dimensioning and/or the composition of the semiconductor material varies within the active zone.

Preferably, as illustrated in FIG. 1 in conjunction with FIG. 3, the variation of the emission wavelength λ₁₁, λ₁₂ and λ₁₃ is embodied such that the emission wavelength decreases in the direction of the coupling-out area 60. As becomes clear from FIG. 3, in particular, this advantageously reduces the reabsorption of the emitted light within the active zone. Thus, by way of example, light emitted by the quantum well with the lowest quantization energy ΔE₁₃ is not absorbed, or is absorbed only to a small extent, by the quantum wells arranged in increasing z direction and hence in the direction of the coupling-out area, since their quantization energy ΔE₁₁ and ΔE₁₃, respectively, is greater than the energy of said light.

FIG. 4A illustrates a plan view of the exemplary embodiment of a multiple light-emitting diode arrangement according to the invention, and FIG. 4B shows the associated side view.

The semiconductor bodies 10, 20 and 30 are arranged in a cutout 70 of a common housing basic body 40. The side walls 80 of the cutout 70 are arranged obliquely in the manner of a reflector and thus increase the luminous efficiency of the component.

The chip and wire terminal regions (not illustrated) assigned to the semiconductor bodies 10, 20 and 30 are led out as terminals A10, C10, A20, C20, A30 and C30 from the housing basic body 40 and extend as far as the mounting side in the manner of a surface-mountable component.

The invention is not restricted by the description on the basis of the exemplary embodiments. In particular, in the case of the invention, it is also possible for a plurality or even all of the semiconductor bodies to have a correspondingly increased spectral bandwidth. The invention furthermore also encompasses all combinations of the features mentioned in the exemplary embodiments and the rest of the description, in particular all combinations of the features mentioned in the patent claims even if these combinations are not explicitly specified in the patent claims or exemplary embodiments.

I claim:

1. A radiation-emitting semiconductor component comprising a plurality of semiconductor bodies (10, 20, 30) which each have an active zone (11, 12, 13) and during operation emit light having in each case a different central wavelength (λ₁₀, λ₂₀, λ₃₀) and an assigned spectral bandwidth (Δλ₁₀, Δλ₂₀, Δλ₃₀),
wherein
in the case of at least one of the semiconductor bodies (10), the emission wavelength (λ₁₀) varies in the active zone (11) in a predetermined manner, so that the spectral bandwidth (Δλ₁₀) of the light emitted by this semiconductor body (10) is increased.

2. The radiation-emitting semiconductor component as claimed in claim 1,
wherein
the emission wavelength (λ₁₀) increases or decreases in the vertical direction within the active zone (11) of the at least one semiconductor body (10).

3. The radiation-emitting semiconductor component as claimed in claim 1,
wherein
the active zone (11) of the at least one semiconductor body (10) has a quantum well structure comprising a plurality of quantum wells having different quantization energy.

4. The radiation-emitting semiconductor component as claimed in claim 1, wherein
the active zone (11) of the at least one semiconductor body (10) contains a semiconductor material whose composition varies within the active zone in a predetermined manner.

5. The radiation-emitting semiconductor component as claimed in claim 4,
wherein
the active zone (11) contains InₓAl_{y}Ga_{1-x-y}p where 0≦x≦1, 0≦y≦1 and 0≦x+y≦1.

6. The radiation-emitting semiconductor component as claimed in claim 1,
wherein
the at least one semiconductor body (10) has a coupling-out area (6) arranged wavelength (λ₁₀) decreases within the active zone (11) in the direction of the coupling-out area (6).

7. The radiation-emitting semiconductor component as claimed in claim 1,
wherein
the plurality of semiconductor bodies comprises a first semiconductor body emitting in the yellow or orange spectral range and a second semiconductor body emitting in the blue or blue-green spectral range.

8. The radiation-emitting semiconductor component as claimed in claim 1,
wherein
the plurality of semiconductor bodies comprises a first semiconductor body emitting in the red spectral range, a second semiconductor body emitting in the green spectral range, and a third semiconductor body emitting in the blue spectral range.

9. The radiation-emitting semiconductor component as claimed in claim 1,
wherein
the semiconductor body (10) having the longest central wavelength (λ₁₀) has a spectral bandwidth (Δλ₁₀) that is increased through variation of the emission wavelength in the active zone (11).

10. The radiation-emitting semiconductor component as claimed in claim 9,
wherein
only in the case of the semiconductor body (10) having the longest central wavelength (λ₁₀) is the spectral bandwidth (Δλ₁₀) increased through variation of the emission wavelength in the active zone (11).

11. The radiation-emitting semiconductor component as claimed in claim 1,
wherein
the spectral bandwidth (Δλ₁₀) of the at least one semiconductor body (10) is greater than or equal to 20 nm, preferably greater than or equal to 30 nm, particularly preferably greater than or equal to 40 nm.

12. The radiation-emitting semiconductor component as claimed in claim 1,
wherein
the spectral bandwidth is increased in the case of one or more of the semiconductor bodies (10, 20, 30) in such a way that the color rendering index of the light emitted by the component is greater than or equal to 60.

13. The radiation-emitting semiconductor component as claimed in claim 1,
wherein
the spectral bandwidth is increased in the case of one or more of the semiconductor bodies (10, 20, 30) in such a way that the color rendering index of the light emitted by the component is greater than or equal to 80.

14. The radiation-emitting semiconductor component as claimed in claim 1,
wherein
the spectral bandwidth is increased in the case of one or more of the semiconductor bodies (10, 20, 30) in such a way that the color rendering index of the light emitted by the component is greater than or equal to 90.

15. The radiation-emitting semiconductor component as claimed claim 1,
wherein
the impression of white light arises as a result of the mixing of the light emitted by the semiconductor bodies.
